(19) United States
(12) Patent Application Publication
(10) Pub. No.: US 2019/0304949 A1
(43) Pub. Date: Oct. 3, 2019

(54) SEMICONDUCTOR PACKAGING METHODOLOGY WITH RECONSTITUTION CONCEPT USING THERMAL AND UV RELEASABLE ADHESIVE ON A CARRIER

(71) Applicant: CHIP SOLUTIONS, LLC, Phoenix, AZ (US)

(72) Inventor: Sukianto Rusli, Phoenix, AZ (US)

(21) Appl. No.: 16/370,680

(22) Filed: Mar. 29, 2019

Related U.S. Application Data
(60) Provisional application No. 62/650,664, filed on Mar. 30, 2018.

(51) Int. Cl. H01L 23/00; H01L 23/31; H01L 21/56

(52) U.S. Cl. CPC H01L 24/83; H01L 23/3121; H01L 21/566; H01L 21/561; H01L 2224/73203; H01L 24/33; H01L 24/73; H01L 24/96; H01L 24/17

(57) ABSTRACT

A method of semiconductor packaging includes providing a plurality of substrate units including at least one good known substrate unit on a first adhesive layer of a first carrier. The method includes applying a first activating source to the first adhesive layer in situ such that the first adhesive layer releases from the at least one good known substrate unit without physical contact by an outside source to the at least one good known substrate unit. The method includes transferring the at least one good known substrate unit onto a second adhesive layer of a second carrier, attaching at least one die to the at least one good known substrate unit, and applying a second activating source to the second adhesive layer such that the second adhesive layer releases from the at least one good known substrate unit.

### CROSS-REFERENCE TO RELATED APPLICATIONS

This application claims priority to U.S. Provisional Application No. 62/650,664, filed Mar. 30, 2018. This application incorporates by reference each of U.S. Provisional Application No. 62/650,664, filed Mar. 30, 2018; U.S. Nonprovisional application Ser. No. 16/278,972, filed Feb. 19, 2019; U.S. Nonprovisional application Ser. No. 15/705,567, filed Sep. 15, 2017; U.S. Nonprovisional application Ser. No. 15/405,700, filed Jan. 13, 2017, now U.S. Pat. No. 9,922,949; U.S. Nonprovisional application Ser. No. 15/211,631, filed Jul. 15, 2016, now U.S. Pat. No. 9,847,244; U.S. Nonprovisional application Ser. No. 15/211,290, filed Jul. 15, 2016, now U.S. Pat. No. 9,941,146; U.S. Nonprovisional application Ser. No. 15/211,384, filed Jul. 15, 2016; U.S. Nonprovisional application Ser. No. 15/211,481, filed on Jul. 15, 2016; U.S. Provisional Patent Application No. 62/388,023 filed Jan. 14, 2016, and U.S. Provisional Patent Application No. 62/231,814 filed Jul. 15, 2015.

### FIELD OF TECHNOLOGY

The subject matter disclosed herein generally relates to the fabrication of semiconductor devices. More particularly, the subject matter relates to a semiconductor device packaging methodology using carriers.

### BACKGROUND

During manufacturing of semiconductor devices, a panel of substrates from a substrate supplier or made by a substrate manufacturer typically includes good substrate units, meaning units that have been tested and found compliant with applicable requirements, and bad substrate units, meaning units that have been tested and found non-compliant with applicable requirements. When a panel or individual strips of a panel goes through an assembly line, both the good and bad substrate units are processed, and in the final step of singulation of the substrates, the bad substrate units are removed. This may result in waste of resources including mold material, particularly with manufacturing of semiconductor devices with complex substrate circuit designs. This happens because bad substrate units are processed, but cannot be used and are rejected along with the components added during assembly processing. In addition, increasing requirements for thinner substrate layers can strain the manufacturing process and contribute to low yield, low efficiency, and high cost.

Various limitations including significant yield loss are inherent in these known manufacturing processes. Therefore, improved methods of manufacturing semiconductor devices would be well received in the art.

### SUMMARY

According to an embodiment, a method of semiconductor packaging comprises providing a plurality of substrate units on a first adhesive layer of a first carrier, wherein the plurality of substrate units includes at least one good known substrate unit; applying a first activating source to the first adhesive layer in situ such that the first adhesive layer releases from the at least one good known substrate unit without physical contact by an outside source to the at least one good known substrate unit; transferring the at least one good known substrate unit onto a second adhesive layer of a second carrier such that the second carrier comprises only good known substrate units; attaching at least one die to the at least one good known substrate unit; and applying a second activating source to the second adhesive layer such that the second adhesive layer releases from the at least one good known substrate unit and the second carrier without physical contact by an outside source to the at least one good known substrate unit.

The present invention advantageously provides a simple method and associated system for forming a semiconductor package.

### BRIEF DESCRIPTION OF THE DRAWINGS

The subject matter which is regarded as the invention is particularly pointed out and distinctly claimed in the claims included at the conclusion of this specification. The foregoing and other features and advantages of the invention are apparent from the following detailed description taken in conjunction with the accompanying drawings in which:

FIG. 1A depicts a top view of a panel having a plurality of substrate units;

FIG. 1B depicts a top view of a strip having substrate units of the plurality of substrate units of FIG. 1A;

FIG. 2A depicts a top view of a strip having a plurality of substrate units;

FIG. 2B depicts a top view of another strip having substrate units of the plurality of substrate units of FIG. 2A;

FIG. 3A shows a side cutaway view of a step of a semiconductor packaging process in accordance with one embodiment;

FIG. 3B shows a side cutaway view of another step of the semiconductor packaging process of FIG. 3A in accordance with one embodiment;

FIG. 3C shows a side cutaway view of another step of the semiconductor packaging process of FIGS. 3A and 3B in accordance with one embodiment;

FIG. 3D shows a side cutaway view of another step of the semiconductor packaging process of FIGS. 3A-3C in accordance with one embodiment;

FIG. 3E shows a side cutaway view of another step of the semiconductor packaging process of FIGS. 3A-3D in accordance with one embodiment;

FIG. 3F shows a side cutaway view of another step of the semiconductor packaging process of FIGS. 3A-3E in accordance with one embodiment;

FIG. 3G shows a side cutaway view of another step of the semiconductor packaging process of FIGS. 3A-3F in accordance with one embodiment;

FIG. 3H shows a side cutaway view of another step of the semiconductor packaging process of FIGS. 3A-3G in accordance with one embodiment;

FIG. 3I shows a side cutaway view of another step of the semiconductor packaging process of FIGS. 3A-3H in accordance with one embodiment;

FIG. 3J shows a side cutaway view of another step of the semiconductor packaging process of FIGS. 3A-3I in accordance with one embodiment;

FIG. 3K shows a side cutaway view of another step of the semiconductor packaging process of FIGS. 3A-3J in accordance with one embodiment;

FIG. 4A shows a side cutaway view of a step of a semiconductor packaging process in accordance with one embodiment;

FIG. 4B shows a side cutaway view of a step of a semiconductor packaging process of FIG. 4A in accordance with one embodiment;

FIG. 4C shows a side cutaway view of a step of a semiconductor packaging process of FIGS. 4A-4B in accordance with one embodiment;

FIG. 5 shows a side cutaway of a carrier having a frame according to one embodiment;

FIG. 6 shows a side cutaway view of a step of a semiconductor packaging process in accordance with one embodiment;

FIG. 7 shows a flow chart illustrating steps of a semiconductor packaging process in accordance with one embodiment.

### DETAILED DESCRIPTION

A detailed description of the hereinafter-described embodiments of the disclosed apparatus and method are presented herein by way of exemplification and not limitation with reference to the Figures.

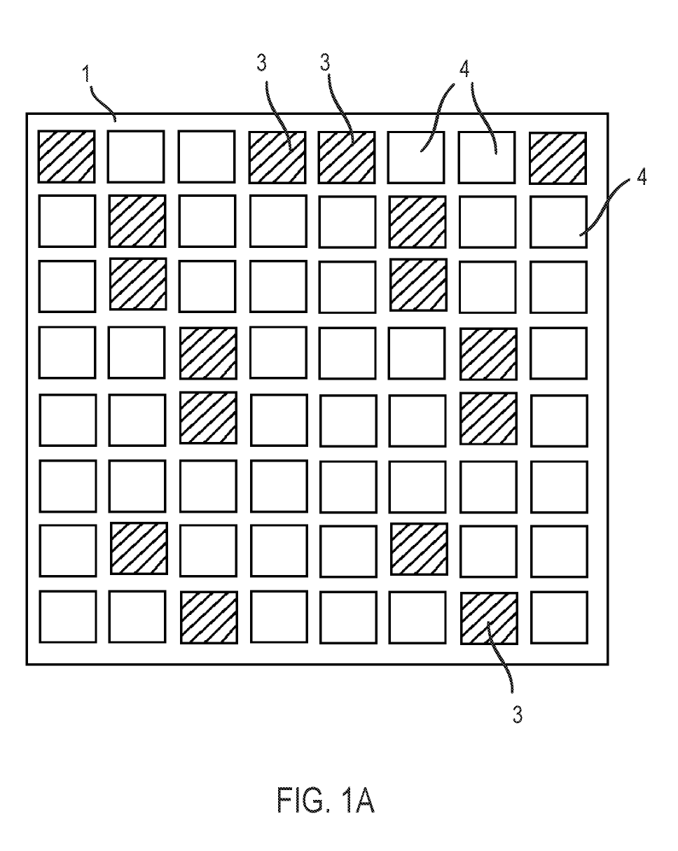

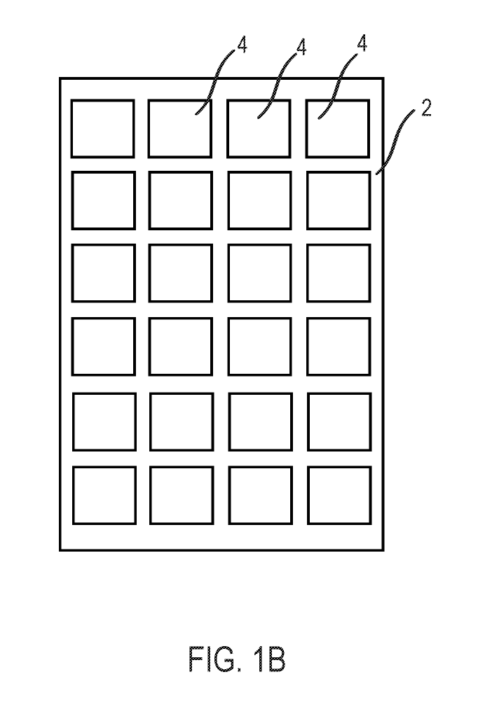

With reference to FIG. 1A, a panel 1 having a plurality of substrate units 3, 4 is shown. The plurality of substrate units 3, 4 on panel 1 have undergone testing to determine which substrate units are compliant with the applicable requirements and are accordingly good known substrate units 4, and which substrate units do not comply with the applicable requirements and are accordingly bad substrate units 3. As an example, testing the plurality of substrate units 3, 4 may involve using a clamp with clamping portions having pins that extend from each clamping portion, such that the pins may contact pads on the top and bottom of each substrate unit of the plurality of substrate units 3, 4 for electrical testing. Using releasable carriers, the good substrate units 4 may be singulated, segregated, and reconstituted onto a strip such that the strip has only good known substrate units 4 as shown in FIG. 1B.

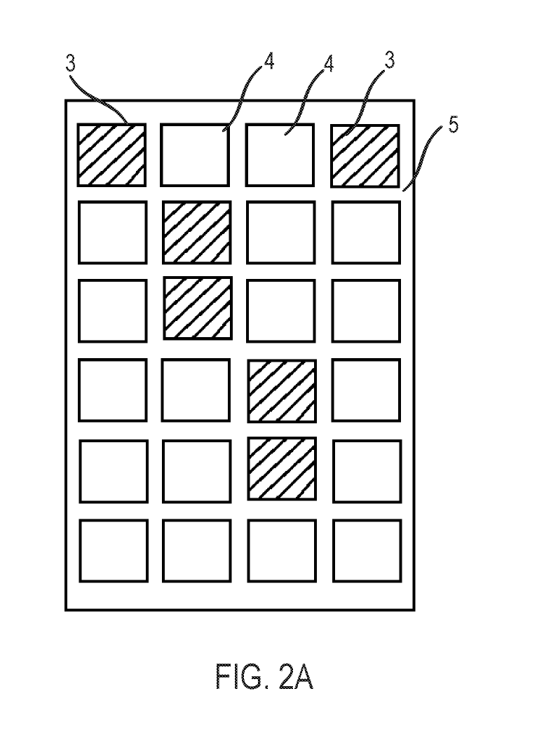

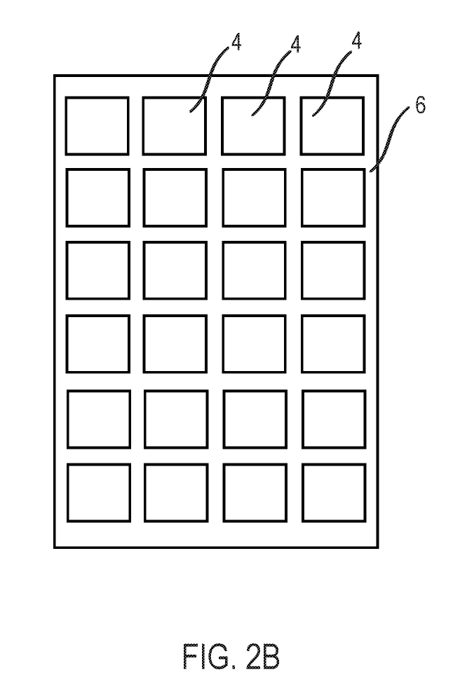

With reference to FIG. 2A, a plurality of substrate units 3, 4 may also be provided on a strip 5. The plurality of substrate units 3, 4 on strip 5 have undergone testing to determine which substrate units are good known substrate units 4, and which substrate units are bad substrate units 3. Likewise, using releasable carriers, the good substrate units 4 on the strip 5 may be singulated, segregated, and reconstituted onto a second strip 6 such that the second strip 6 has only good known substrate units, as shown in FIG. 2B. Singulating, segregating, and reconstituting the good known substrate units 4 as shown in FIGS. 1B and 2B helps ensure only good known substrate units 4 undergo further processing, and ensures that only good known substrate units are attached to good known dies. By processing only good known substrate units 4—for example attaching dies, molding, and attaching solder balls thereto—time, resources, and materials are not wasted by processing the bad substrate units 3 that cannot be used.

To reconstitute good known substrate units 4, releasable carriers having an adhesive layer that is releasable by an activating source such that no physical contact by an outside source is applied to the good known substrate units thereon may be used. For example, no bending, manipulating, or moving the good known substrates is required to release the adhesive layer from the good known substrate units. For example, an adhesive layer may be configured such that when an activating source is applied to the adhesive layer, the adhesive layer releases from the good known substrate units with no physical contact by an outside source with the adhesive layer, the releasable carrier, and the good known substrate units thereon. The releasable carrier onto which only the good known substrate units 4 are reconstituted provides structural support for the good known substrate units 4 in an assembly process. When the good known substrate units 4 have undergone processing, the releasable carrier onto which the good known substrate units 4 were reconstituted can be removed by applying an activating source to an adhesive layer on that releasable carrier, so that assembly may be completed and the good known substrate units may be singulated to create semiconductor devices. Different types of releasable carriers and methods may be used for reconstitution and semiconductor packaging processes.

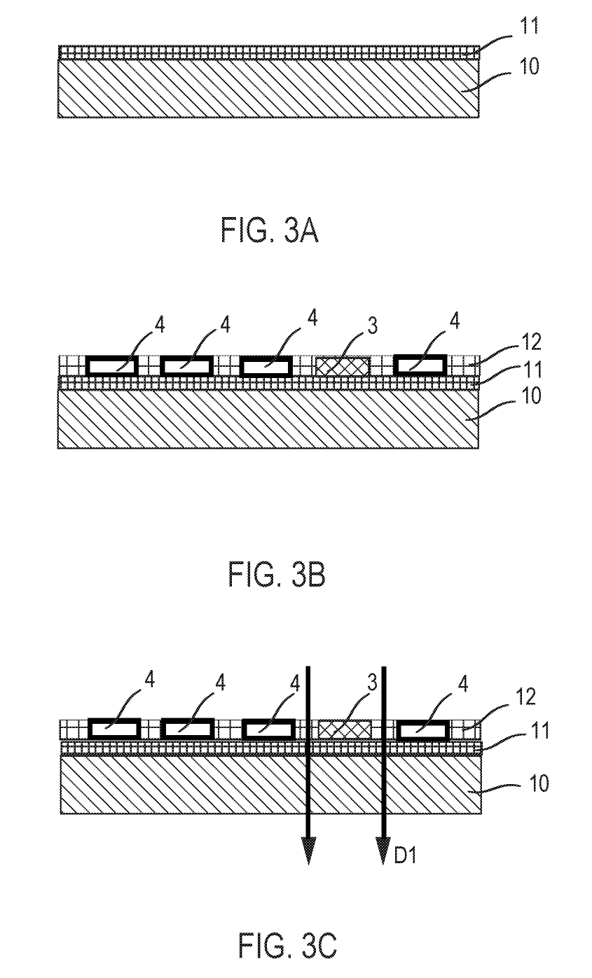

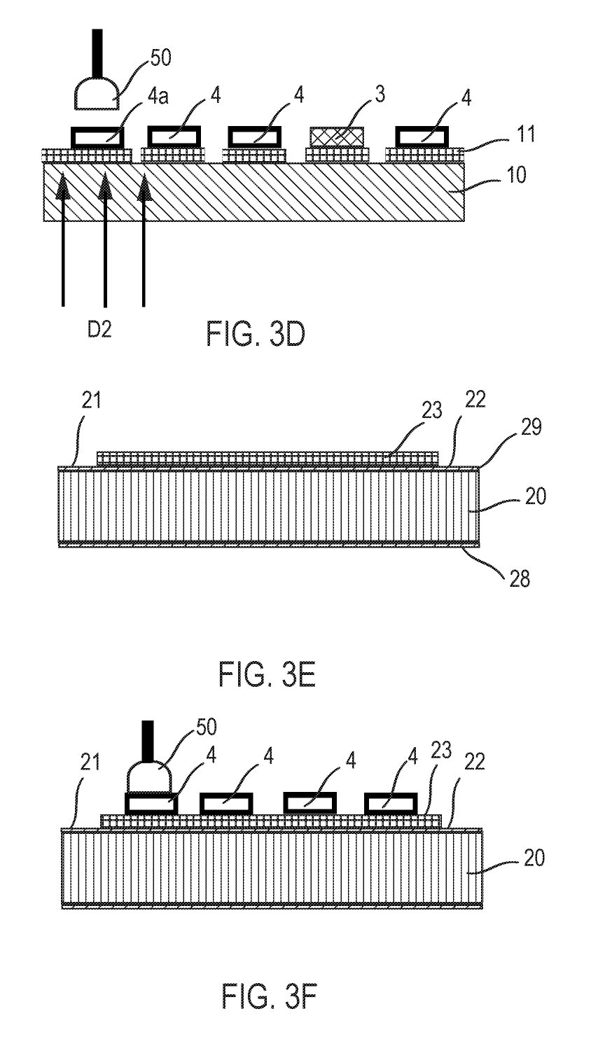

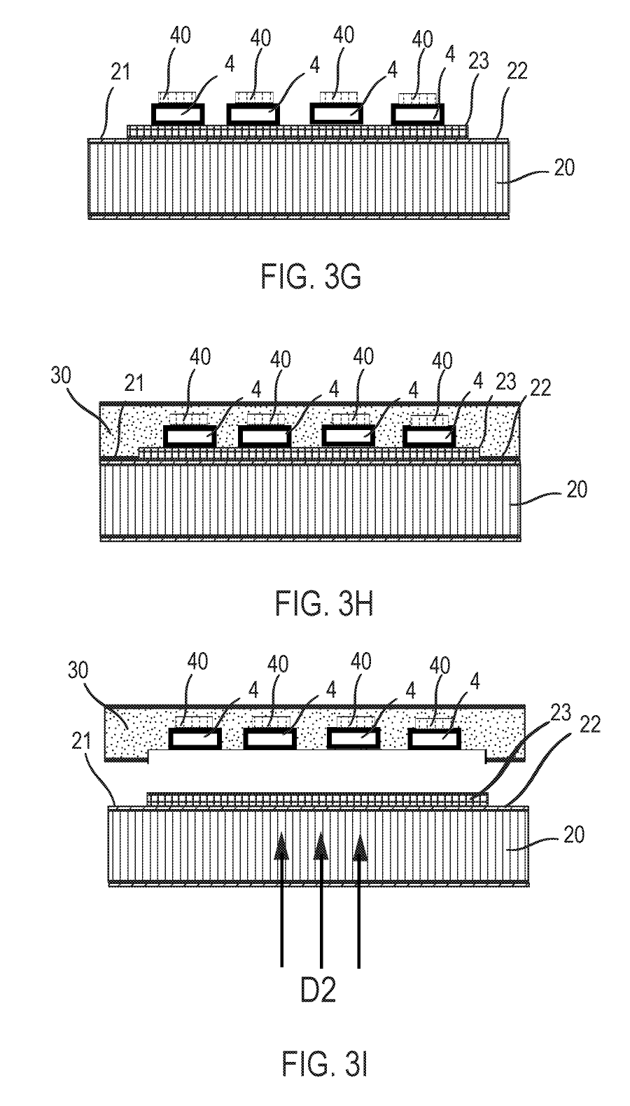

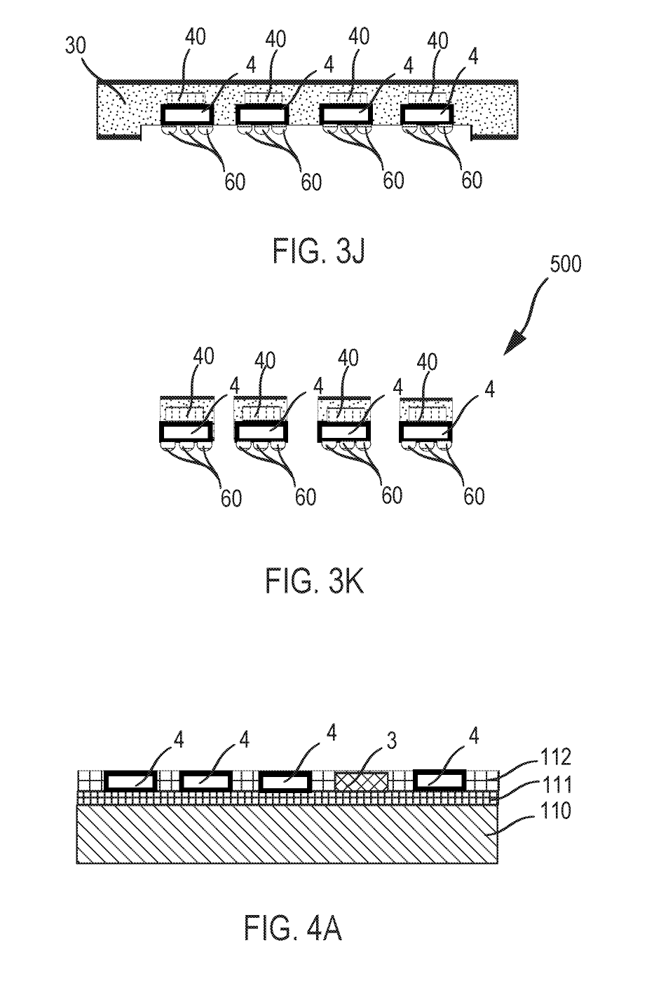

With reference to FIGS. 3A-3J, an embodiment of a semiconductor packaging method using a reconstitution process is shown. Referring to FIG. 3A, a first releasable carrier 10 is shown. The first releasable carrier 10 is made of transparent glass and includes a first adhesive layer 11 which may be laminated onto the glass first releasable carrier 10. In this embodiment, the first adhesive layer 11 is configured to be activated by an activating source that can travel through the transparent glass carrier to activate and release the first adhesive layer 11. For example, the first adhesive layer 11 may be activated by an ultraviolet (UV) activation source. The first adhesive layer 11 may be a 3M® adhesive, a releasable tape, a double-sided releasable tape, a releasable adhesive film, an adhesive material, and the like. As one example, the first adhesive layer 11 may be a 3M® Light-to-Heat Conversion (“LTHC”) adhesive which may provide lower temperature release, for example, 90 degrees Celsius or higher temperature release, for example, 260 degrees Celsius. The first releasable carrier 10 may be made of any material through which an activating source can reach and activate the first adhesive layer 11.

Referring to FIG. 3B, a side cutaway view of another step of the semiconductor packaging method shown in FIG. 3A is shown. Particularly, a strip or panel 12 (such as panel 1 or strip 3) having good known substrate units 4 and bad substrate units 3 is shown laminated onto the adhesive layer 11. In another embodiment, rather than a panel or strip of premade substrate units 3, 4 being provided and laminated on the first releasable carrier 10, substrate units may be built up on the first releasable carrier 10. For example, the first releasable carrier 10 may have a metal foil layer such as a copper foil layer laminated on the first adhesive layer 11, and substrate units may be built up on the metal foil layer. The first adhesive layer 11 is configured such that when an activating source is applied, the first adhesive layer 11 releases from the substrate units 3, 4 without physical contact by an outside source to the substrate units 3, 4. For example, no mechanical bending or manipulation of the substrate units 3, 4 is required to release the first adhesive layer from the substrate units 3, 4.

The substrate units 3, 4 on the first releasable carrier 10 have undergone testing, for example, operational testing, and electrical testing, to identify good known substrate units 4 and bad substrate units 3. Electrical testing may include transferring the substrate units 3, 4 to an electrical test carrier having a releasable adhesive layer, and testing the substrate units 3, 4 to determine whether the substrate units 3, 4 fulfill all applicable requirements. Substrate units that fulfill all applicable requirements may be marked or designated as good known substrate units, and substrate units that do not fulfill all applicable requirements may be marked or designated as bad substrate units. After electrical testing, the substrate units 3, 4 may be transferred from the electrical test carrier to a releasable carrier having a releasable adhesive layer, such as the first releasable carrier 10.

In one embodiment, the substrate units 3, 4 may be built on the first releasable carrier 10. The substrate units 3, 4 may then be transferred to an electrical test carrier having a releasable adhesive layer, and the first releasable carrier 10 may be released by activating the first adhesive layer 11. The substrate units 3, 4 may then undergo testing. Then, the substrate units 3, 4 may be transferred back to the first releasable carrier 10. In this embodiment, the first releasable carrier 10 may be reused and the substrate units 3, 4 may be placed back on a new adhesive layer on the first releasable carrier 10. The first releasable carrier 10 may then support the substrate units 3, 4 during singulation and segregation of good known substrate units 4 (as shown in FIGS. 3C and 3D and described hereinafter). In another embodiment, the substrate units 3, 4 may be built on a different releasable carrier and then transferred to the first releasable carrier 10 after testing. The first releasable carrier, first adhesive layer, substrate units, and testing of the substrate units in a semiconductor packaging process using a reconstitution method may incorporate some or all embodiments described by the patents and patent applications incorporated by reference.

In FIG. 3C, a side cutaway view of another step of the semiconductor packaging process shown in FIGS. 3A-3B is shown. The good known substrate units 4 are shown being singulated such that the good known substrate units 4 may be segregated from the bad substrate units 3. Singulation may be performed by in situ laser cutting, shown in FIG. 3C in direction D1. Singulation may also be performed by mechanical cutting by a saw. The first releasable carrier 10 provides support to the substrate units 3, 4 during singulation of the good known substrate units 4. The depth of the singulation may be controlled. For example, laser ablation may be performed such that the laser beam passes completely or partially through the good known substrate units 4, the first adhesive layer 11, and first releasable carrier 10. As another example, laser cutting may be performed such that the laser beam passes through the good known substrate units 4 and stops at a controlled depth in the first adhesive layer 11. As another example, the singulation process may cut through the first adhesive layer 11 completely. As yet another example, the singulation process may be configured such that the laser or mechanical saw does not reach the first releasable carrier 10. In the case of a glass carrier, laser ablation may be performed such that the laser beam passes through the carrier. In another embodiment, a laser beam may singulate the good known substrate units 4 and pass through the first adhesive layer 11, and stop at the carrier, for example, where the carrier is metal.

In some embodiments, the first releasable carrier 10 may be a copper clad laminate and the first adhesive layer 11 may be configured to be activated by a thermal activation source. In this embodiment, the first adhesive layer 11 of the first releasable carrier 10 may be configured to be activated and release by a thermal activating source at a temperature of, for example, 90 degrees Celsius, as the singulation process of the good known substrate units 4 may be done at room temperature, and the first releasable carrier and first adhesive layer may not be required to go through a greater temperature reflow process.

After singulation, the good known substrate units 4 may be segregated by in situ release from the bad substrate units 3 and then transferred to a second releasable carrier 20 (shown in FIG. 3E and described hereinafter) for further processing such as assembly. With reference to FIG. 3D, another step of the semiconductor packaging method shown in FIGS. 3A-3C, is shown in which an activating source is being applied direction D2 and in situ to the first adhesive layer 11 underneath good known substrate 4a. The activating source may be a LTHC laser. The activating source moves through the glass of the first releasable carrier 10 to the first adhesive layer 11, and the first adhesive layer 11 is activated in situ, such that good known substrate 4a is released and can be transferred to the second releasable carrier 20. Each good known substrate unit 4 may undergo in situ release such that the first adhesive layer 11 is activated and releases only the good known substrate unit 4 being transferred to the second releasable carrier at a given time, and such that other substrate units are not released. During the in situ release of each good known substrate unit 4, no physical force or touch is applied to the good known substrate units. For example, no mechanical manipulation, peeling or bending of the good known substrate units 4 is required. The in situ release preserves the structural integrity of the good known substrate units 4 during reconstitution and prevents bending and warpage that can damage the good known substrate units 4. In situ release of the good known substrate units 4 from the first adhesive layer is performed such that no residue remains on the good known substrate units 4 from the first adhesive layer. The release of the first adhesive layer 11 from the first releasable carrier 10 allows the first releasable carrier 10 to be reused. Reuse of the first releasable carrier 10 may include removing residue left by the first adhesive layer 11 after the first adhesive layer 11 has been released. As shown in FIG. 3D, a pick and place head 50 of a pick and place machine may be used to pick and transfer the good known substrate 4a to the second releasable carrier 20.

Transferring the good known substrate units 4 to a second releasable carrier 20 may include temporary holding of the good known substrate units 4 during the transfer process to prevent substrate movement. Substrate movement may be warping, bending, folding, deformation and the like, or movement similar to how a sheet of paper moves when lifted. Preventing movement helps keep substrate units intact and in place to avoid problems during subsequent assembly processes such as registration issues between substrates, between substrate layers, and between substrates and other semiconductor device components. Temporary holding of the good known substrate units 4 during transfer may be particularly advantageous the thinner the good known substrate units 4 are. Good known substrate units 4 that are thick enough that they do not warp, bend, fold, or otherwise move during transfer may not require any temporary holding.

With reference to FIG. 3E, another step of the semiconductor packaging process of FIGS. 3A-3D is shown. In this step, a second releasable carrier 20 is provided. In this embodiment, the second releasable carrier 20 is a copper clad laminate. The second releasable carrier 20 may be strip or panel format, or another format. The second releasable carrier 20 has a second adhesive layer 23. The second adhesive layer 23 is laminated on the second releasable carrier 20. The second adhesive layer 23 is configured to withstand assembly process temperature requirements, for example, temperatures required for reflow processing, in order that delamination is prevented and release by the second adhesive layer 23 is not activated at an undesired time in the assembly processes. In the embodiment shown in FIG. 3E second adhesive layer 23 is releasable by a thermal activation source. For example, the second adhesive layer 23 may be thermal-release releasable adhesive produced by Nitto, for example, “REVALPHA” that has a release temperature, meaning the temperature at which the release of the releasable adhesive is activated, at a low-temperature for example, 90 degrees Celsius. With respect to reusing the second releasable carrier, Nitto thermal release releasable adhesive may provide a cleaner release with less residue to remove from the second releasable carrier than UV-activated releasable adhesive. The release temperature may be a higher temperature for example 200 degrees Celsius. The second releasable carrier 20 may be made of any material through which an activating source can reach and activate the second adhesive layer 23, such as by induction heating. In addition to being releasable, the second releasable carrier 20 may be reusable. Reusing the second releasable carrier 20 may include removing any residue left by the second adhesive layer 23.

The second releasable carrier 20 and first releasable carrier 10 are not limited to being transparent glass or copper clad laminate, and could be made of other materials, for example, aluminum, stainless steel, or other materials. For example, where a releasable carrier is made of transparent glass, the activating source may be thermal or UV; where a releasable carrier is made of copper clad laminate or metal, the activating source may be thermal. Likewise, a UV-release adhesive layer may be used with a carrier of any material that permits the UV activating source to move through the carrier to reach and activate the UV-release adhesive layer, and a thermal-release adhesive layer may be used with a carrier of any material that permits the thermal-activating source to reach and activate the thermal-release adhesive layer. As an example, the first releasable carrier may be a copper clad laminate having a thermal-release first adhesive layer. In situ application of a thermal activating source to release a singulated good known substrate unit 4 may include applying heat with a block having dimensions of the good known substrate unit to be released such that the heat activates the first adhesive layer to release the good known substrate unit without releasing from any other substrate units on the first adhesive layer.

As shown in FIG. 3E, the second adhesive layer 23 may be applied such that there are areas 21, 22 of the second releasable carrier 20 not covered with the second adhesive layer 23. These areas may be configured as mold gates or mold channels 21. One or more fiducials 22 may also be defined on the second releasable carrier 20. The mold gates 21 are configured such that mold material 30 (shown in FIG. 3H and described hereinafter) may enter the mold gates 21 and encapsulate good known substrates 4 and other components added during the assembly process. Mold gates may be patterned on the second releasable carrier 20.

As shown in FIG. 3F, another step of the semiconductor packaging method of FIGS. 3A-3E is shown. The good known substrate units 4 are being transferred to the second releasable carrier 20 by the pick and place head 50 such that the second releasable carrier 20 has 100% good known substrate units 4. The good known substrate units 4 are securely adhered to the second adhesive layer 23. For example, the good known substrate units 4 may be rolled or pressed to further ensure the good known substrate units 4 remain adhered to the second adhesive layer, and therefore, remain supported by the second releasable carrier 20 throughout the assembly process. The second releasable carrier, second adhesive layer, and assembly process described hereinafter in a semiconductor packaging process using a reconstitution method may incorporate some or all embodiments described by the patents and applications incorporated by reference.

With reference to FIGS. 3G-3J, the second releasable carrier 20 is shown carrying the good known substrates 4 through an assembly process. An assembly process may include the step of attaching a die 40, as shown in FIG. 3G. The die attach method is selected such that the die attach process is performed at a lower temperature than the temperature at which the thermal-activated second adhesive layer 23 is activated. As an example, the thermal-activated second adhesive layer 23 may have a release temperature that is lower than the temperature at which a standard reflow process takes place. For example, Nitto thermal release adhesive may be activated to release at 200 degree Celsius, and a standard reflow process may take place at a 260 degree Celsius temperature. In this instance, a lower-temperature assembly process, such as localized in situ die attach methods, would be required to avoid undesired de-lamination of the Nitto thermal release adhesive during die-attach. Localized die attach methods such as Laser Assisted Bonding (LAB), Laser Assisted Die (“LAD”) attach, for example, using an infrared laser may be used. Other methods include attachment with non-conductive paste, (“NCP”), nonconductive film (“NCF”), Gang Bonding, or any other localized die attach methods. As an example, using Laser Assisted Bonding, during die attach, the good known substrate units 4 may absorb heat of the die attach process, and the application of heat may take a short amount of time such that heat does not reach and activate release of the second adhesive layer 23. Low-temperature reflow solder balls may be used for die attach such that the second adhesive layer 23 is not activated during die attach.

As shown in FIG. 3H, another step of the semiconductor packaging process of FIGS. 3A-3G is shown in which a transfer molding method is used to encapsulate the good known substrates 4 and added components, such as dies 40. A mold material 30 is shown having been applied to the good known substrate units 4. The molding process may be transfer molding or compression molding, or another molding method. The mold material 30 may be a mold compound, a mold sheet, and a powder or liquid molding compound or system. In some embodiments, the mold material 30 may be a dielectric material instead of a mold material, such as ABF film. Capillary underfill and mold underfill may be used.

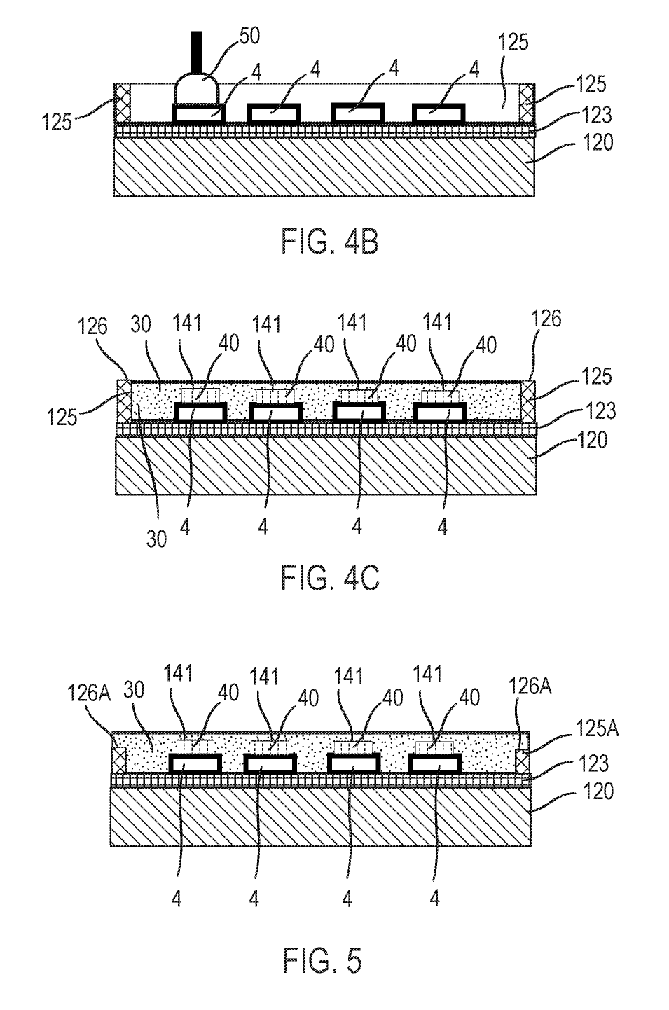

In the case of transfer molding, a frame area is used to define the area to be encapsulated, and to provide a mold gate feature and other tooling features such as fiducials. A mold gate 21 allows mold material 30 to enter the area to be encapsulated. A frame area may be created by patterning and forming a frame onto the second releasable carrier 20 without having to attach a separate frame to the second releasable carrier 20. As shown in FIG. 3H, the frame area is defined by a surface area including areas 21, 22 of the second releasable carrier 20 where the second adhesive layer 23 does not extend. Another option is to attach or laminate a separate frame 125 (shown in FIG. 4B and described hereinafter) onto the second releasable carrier 20. As shown in FIG. 3H, the mold gate 21 provides an area through which the mold material may enter and encapsulate the good known substrates 4 and other components such as dies 40. Where compression molding is used, a mold gate 21 may not be required.

As shown in FIG. 3I, another step of the semiconductor packaging process shown in FIGS. 3A-3H is shown in which a thermal activating source is being applied in direction D2 to the underside of the second releasable carrier 20 such that the second adhesive layer 23 is heated to a temperature at which the second adhesive layer 23 is activated and releases the encapsulated good known substrate units 4. Application of the activating source to release the encapsulated good known substrate units 4 may be done in situ. The encapsulated good known substrate units 4 are released from the second releasable carrier 20 without physical force or contact applied by an outside force to the encapsulated good known substrate units 4. For example, no mechanical peeling or bending is required, thereby maintaining the structural integrity of the good known substrate units 4.

With reference to FIG. 3J a side cutaway view of another step of the semiconductor packaging process shown in FIGS. 3A-3I is shown in which solder balls 60 are applied to Ball Grid Array (“BGA”) pads exposed on the bottom of the good known substrates 4 after the second releasable carrier 20 and second adhesive layer 23 are released from the good known substrate units 4.

With reference to FIG. 3K, a side cutaway view of another step of the semiconductor packaging process shown in FIGS. 3A-3J is shown. After solder ball 60 attach, the good known substrate units 4 may be singulated, such as by in situ laser cutting such as laser ablation, or mechanical saw cutting, to create semiconductor devices 500 as shown in FIG. 3K. Using the reconstitution process such that only good known substrate units 4 are included on second releasable carrier 20 helps ensure that materials such as mold, dies, and other components are wasted by being assembled on bad substrate units 3 that cannot be used.

With reference to FIGS. 4A-4C, another embodiment of a semiconductor packaging process using a reconstitution method is shown in which the second releasable carrier 120 (shown in FIG. 4B and described hereinafter) is a transparent glass carrier, the second adhesive layer 123 is a UV-release adhesive layer, and the molding process is facilitated by a separate frame 125 (shown in FIG. 4B and described hereinafter) attached to the second releasable carrier 120.

FIG. 4A shows a side cutaway view of a step of a semiconductor packaging process. A first releasable carrier 110 having a first adhesive layer 111 laminated thereon is shown having been provided. The first releasable carrier 110 in this embodiment is a glass carrier, and the first adhesive layer 111 is a UV-activated adhesive layer configured to release from the first releasable carrier 110 and any components attached thereto, without any physical force or contact applied to the substrate units 3, 4 on the first releasable carrier. A strip or panel 112 having good known substrate units 4 and bad substrate units 3 is shown laminated on the first adhesive layer 111. In another embodiment, the substrate units 3, 4, may be built up on the first releasable carrier 110 as described above with respect to first releasable carrier 10. In the embodiment shown in FIG. 4A, the good known substrate units 4 are singulated in situ and released in situ in the same manner as described above with respect to FIGS. 3C-3D.

As shown in FIG. 4B, a side cutaway view is shown of another step of the semiconductor packaging process shown in FIG. 4A in which the good known substrate units 4 are reconstituted onto a second releasable carrier 123 such that the second releasable carrier 123 has only good known substrate units 4. In this embodiment, the second releasable carrier 120 is a transparent glass carrier. The second releasable carrier 120 has a second adhesive layer 123 configured to release from good known substrate units 4 and the second releasable carrier 120 without any physical force or touch applied to the good known substrate units 4 attached to the second adhesive layer 123. In this embodiment, the second releasable carrier 120 also includes a frame 125. The frame 125 may be attached or laminated onto the second adhesive layer 123. In another embodiment, the frame 125 may be attached or laminated directly onto the second releasable carrier 120, in which case the second adhesive layer 123 may be configured such that the second adhesive layer 123 does not cover the entire surface of the second releasable carrier 120. Attaching or laminating a separate frame such as frame 125 onto the second adhesive layer 123 of the second releasable carrier 120 may be preferable where additional rigidity of the molded area is desired, for example, during molding, and after the second releasable carrier 120 and second adhesive layer 123 have been released from the good known substrates 4. The frame 125 may be configured to define the mold area, and includes a mold gate. In the case of providing and attaching or laminating a separate frame such as frame 125, the attaching or laminating of the frame 125 may take place before or after transferring the good known substrate units 4 from the first releasable carrier 110 to the second releasable second carrier 120.

With reference to FIG. 4C, a side cutaway view of another step of the semiconductor packaging process of FIG. 4A-4B is shown. Dies 40 have been attached to the good known substrate units. In embodiments in which the second adhesive layer 123 is UV-activated and not activated to release at temperatures of a standard reflow process, a standard reflow process may be used for die attach. Other die attach methods may be used. The die attach method used is selected such that the die attach method used does not activate the second adhesive layer 123 at an undesired time. In FIG. 4C, transfer molding has been used to encapsulate the good known units 4 and dies 40 with a mold material 30.

In the embodiment shown in FIG. 4C, a top surface 126 of the frame 125 is taller than the top surfaces 141 of the dies 40. In this embodiment the frame 125 may be referred to as a “thick frame.” In another embodiment, a frame may be shorter than the dies 40 such that a top surface of the frame does not extend about the top surfaces 141 of the dies 40, as shown in FIG. 5 and described hereinafter. After transfer molding, a UV activating source may be applied to the underside of the second releasable carrier 120 such that the UV activating source reaches and activates the second adhesive layer 123 and releases the encapsulated good known substrate units 4 without physical force or contact applied to the encapsulated good known substrate units 4. Next, the frame 125 may be cut away and removed from the encapsulated good known substrate units 4 and the second releasable carrier 120. For example, a UV activating source may be applied in situ to the second adhesive layer 123 such that the frame 125 releases from the second adhesive layer 123 and may be removed from the encapsulated good known substrate units 4. Ball attach and in situ singulation may be performed to create semiconductor units in the manner described above with respect to FIGS. 3J and 3K. As another example, the frame may be removed after a ball attach process is completed.

With reference to FIG. 5, a side cutaway of a second releasable carrier having a frame 125A according to another embodiment is shown. In this embodiment, frame 125A may be referred to as a “thin frame.” A top surface 126A of the frame 125A is below the top surfaces 141 of the dies 40. A thin frame may be preferable where the good known substrate units 4 are going to be rolled or pressed onto the second adhesive layer, because if the frame 125 is a thick frame and is attached before good known substrate units 4 are transferred to the second adhesive layer, the roller or press may be unable to reach the surfaces of the good known substrate units 4. Frame thickness specification may be used to control mold flow during a transfer molding process. In the case of providing and attaching or laminating a separate frame 125, the attaching or laminating of the separate frame may take place before or after the placing of the good known substrate units from the first adhesive layer 111 of the first releasable carrier 112 to the second adhesive layer 123 of the second releasable carrier 120.

In another embodiment, the second releasable carrier may be a copper clad laminate having a thermal-activated adhesive layer and a thick or thin frame may be used.

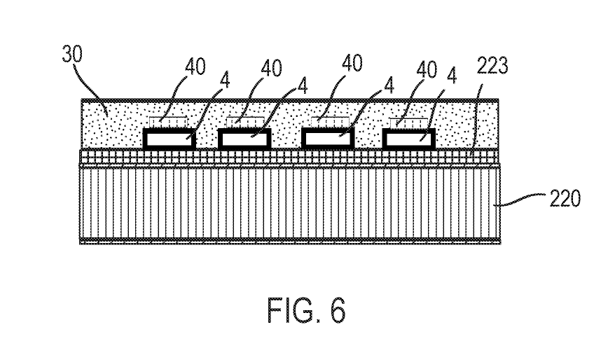

With reference to FIG. 6, another embodiment is shown in which, after the good known substrate units have been reconstituted onto a second releasable carrier 220, and after die 40 attach, a compression molding process is be used to encapsulate the good known substrate units 4 with a mold material 30. In the embodiment shown in FIG. 6, the second releasable carrier 220 is a copper clad laminate. The second releasable carrier has a second adhesive layer 223. No frame is needed for compression molding. A compression molding process may also be used in embodiments in which the second releasable carrier is a transparent glass carrier having a UV-release second adhesive layer.

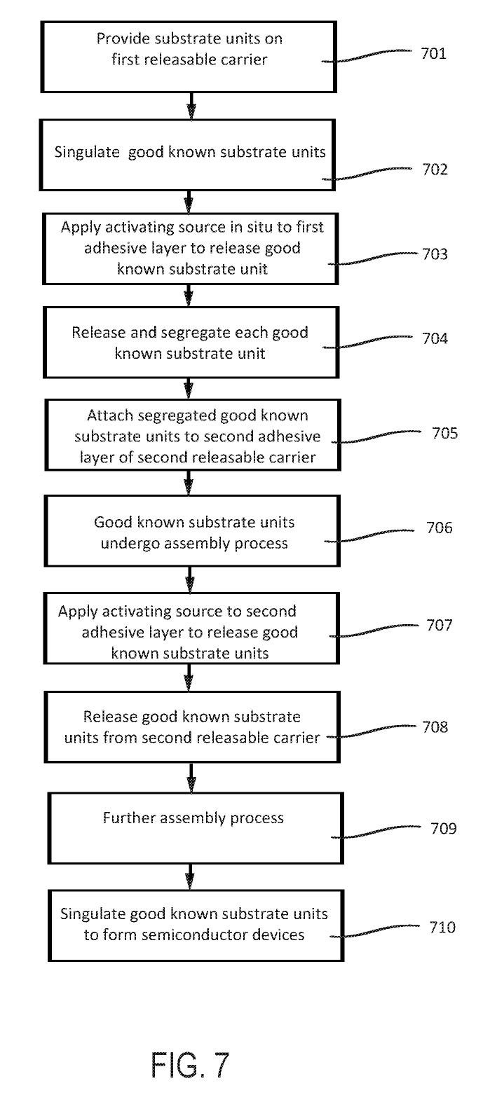

With reference to FIG. 7, a flow chart illustrating a method of reconstituting good known substrate units is shown. In step 701, substrate units that have undergone testing to determine which substrate units are good known substrate units are provided on a first releasable carrier. In step 702, each good known substrate unit is singulated. In step 703, a first activating source is applied in situ to the first adhesive layer to release a good known substrate unit. This step may be applied for each good known substrate unit on the first releasable carrier. In step 704, each good known substrate unit is released from the first adhesive layer and segregated from bad substrate units. In step 705 the good known substrate units are attached to a second adhesive layer of a second releasable carrier. In step 706, the good known substrate units undergo an assembly process which may include die attach and molding. In step 707, a second activating source is applied to the second adhesive layer to release the good known substrate units. In step 708 the good known substrate units are released from the second adhesive layer releasable carrier. In step 709, the good known substrate units undergo further assembly, for example, solder ball attachment. In step 710, the good known substrate units are singulated to form semiconductor devices.

A method of semiconductor packaging may include providing a plurality of substrate units, such as substrate units 3, 4, on a first adhesive layer such as first adhesive layer 11, 111, of a first carrier, such as first releasable carrier 10, 110, wherein the plurality of substrate units includes at least one good known substrate unit. The method may include applying a first activating source to the first adhesive layer in situ such that the first adhesive layer releases from the at least one good known substrate unit without physical contact by an outside source to the at least one good known substrate unit. The method may further include transferring the at least one good known substrate unit onto a second adhesive layer, such as second adhesive layer 23, 123, of a second carrier, such as second releasable carrier 20, 120, such that the second carrier comprises only good known substrate units. The method may include attaching at least one die, such as die 40, to the at least one good known substrate unit, and applying a second activating source to the second adhesive layer such that the second adhesive layer releases from the at least one good known substrate unit and the second carrier without physical contact by an outside source to the at least one good known substrate unit.

The method may further include singulating the at least one good known substrate unit.

The method may include encapsulating the at least one good known substrate unit with a mold material, such as mold material 30, after the attaching at least one die to the at least one good known substrate unit. In an embodiment, the encapsulating the good known substrate units with a mold material may be performed by transfer molding. In an embodiment, the second carrier may include at least one mold gate defined by a surface area portion of the second carrier that is not covered by the second adhesive layer. In an embodiment, the second carrier includes at least one mold gate patterned onto the second carrier. In another embodiment, the encapsulating the good known substrate unit with a mold material may be performed by compression molding.

The method may include attaching a ball to the at least one good known substrate unit; and singulating the at least one good known substrate unit after the attaching the at least one die and attaching a ball.

The method may include laminating the plurality of substrate units onto the first adhesive layer.

The method may include building the plurality of substrate units on the first carrier.

In an embodiment of the method, singulating the good known substrate units on the first adhesive layer may be performed by in situ laser cutting.

In an embodiment of the method, the first carrier and second carrier may be reusable.

In an embodiment the first carrier may be made of transparent glass and the first activating source may be UV. In another embodiment, the first carrier may be made of copper clad laminate and the first activating source may be thermal.

In an embodiment, the second carrier may be made of glass and the second activating source may UV. In another embodiment, the second carrier may be made of copper clad laminate and the second activating source may be thermal.

In an embodiment, the first adhesive layer may be configured to be activated by the first activating source at a lower temperature than the second adhesive layer.

In an embodiment, the attaching at least one die to the at least one good known substrate unit may be performed such that the second adhesive layer does not release the at least one good known substrate unit during the attaching at least one die to the at least one good known substrate unit.

In an embodiment, the transferring the at least one good known substrate unit onto a second adhesive layer of a second carrier may include holding the at least one good known substrate unit such that the at least one good known substrate unit does not deform during transferring.

Elements of the embodiments have been introduced with either the articles “a” or “an.” The articles are intended to mean that there are one or more of the elements. The terms “including” and “having” and their derivatives are intended to be inclusive such that there may be additional elements other than the elements listed. The conjunction “or” when used with a list of at least two terms is intended to mean any term or combination of terms. The terms “first” and “second” are used to distinguish elements and are not used to denote a particular order.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

What is claimed is:

1. A method of semiconductor packaging comprising:
providing a plurality of substrate units on a first adhesive layer of a first carrier, wherein the plurality of substrate units includes at least one good known substrate unit;
applying a first activating source to the first adhesive layer in situ such that the first adhesive layer releases from the at least one good known substrate unit without physical contact by an outside source to the at least one good known substrate unit;
transferring the at least one good known substrate unit onto a second adhesive layer of a second carrier such that the second carrier comprises only good known substrate units;
attaching at least one die to the at least one good known substrate unit; and
applying a second activating source to the second adhesive layer such that the second adhesive layer releases from the at least one good known substrate unit and the second carrier without physical contact by an outside source to the at least one good known substrate unit.

2. The method of claim 1, further including:
singulating the at least one good known substrate unit.

3. The method of claim 1, further including encapsulating the at least one good known substrate unit with a mold material after the attaching at least one die to the at least one good known substrate unit.

4. The method of claim 3, wherein the encapsulating the good known substrate units with a mold material is performed by transfer molding.

5. The method of claim 4, wherein the second carrier includes at least one mold gate defined by a surface area portion of the second carrier that is not covered by the second adhesive layer.

6. The method of claim 4, wherein the second carrier includes at least one mold gate patterned onto the second carrier.

7. The method of claim 4, wherein the second carrier includes a frame defining a mold area during the encapsulating the at least one good known substrate unit with a mold material.

8. The method of claim 3, wherein the encapsulating the good known substrate unit with a mold material is performed by compression molding.

9. The method of claim 1, further including
attaching a ball to the at least one good known substrate unit; and
singulating the at least one good known substrate unit after the attaching the at least one die and attaching a ball.

10. The method of claim 1, further including laminating the plurality of substrate units onto the first adhesive layer.

11. The method of claim 1, further including building the plurality of substrate units on the first carrier.

12. The method of claim 2, wherein the singulating the good known substrate units on the first adhesive layer is performed by in situ laser cutting;

13. The method of claim 1, wherein the first carrier and second carrier are reusable.

14. The method of claim 1, wherein the first carrier is made of transparent glass and the first activating source is UV.

15. The method of claim 1, wherein the first carrier is made of copper clad laminate and the first activating source is thermal.

16. The method of claim 1, wherein the second carrier is made of glass and the second activating source is UV.

17. The method of claim 1, wherein the second carrier is made of copper clad laminate and the second activating source is thermal, wherein the attaching at least one die to the at least one good known substrate unit is performed such that the second adhesive layer does not release the at least one good known substrate unit during attaching the at least one die, wherein the die is attached to the at least one good known substrate by laser assisted bonding.

18. The method of claim 1, wherein the first adhesive layer is configured to be activated by the first activating source at a lower temperature than the second adhesive layer.

19. The method of claim 1, wherein the transferring the at least one good known substrate unit onto a second adhesive layer of a second carrier includes holding the at least one good known substrate unit such that the at least one good known substrate unit does not deform during transferring.
